(19) United States
(12) Patent Application Publication
(10) Pub. No.: US 2022/0262971 A1
(43) Pub. Date: Aug. 18, 2022

(54) MIRROR FOR A PHOTOVOLTAIC CELL, PHOTOVOLTAIC CELL AND PHOTOVOLTAIC MODULE

(71) Applicants: CENTRE NATIONAL DE LA RECHERCHE SCIENTIFIQUE, Paris (FR); UNIVERSITE PARIS-SACLAY, Gis-sur-Yvette (FR)

(72) Inventors: Stéphane COLLIN, Cachan (FR); Louis GOUILLART, Cachan (FR); Andrea CATTONI, Antony (FR); Negar NAGHAVI, Paris (FR)

(21) Appl. No.: 17/606,205

(22) PCT Filed: Apr. 23, 2020
(86) PCT No.: PCT/EP2020/061358

§ 371 Date: Oct. 25, 2021

(30) Foreign Application Priority Data
Apr. 25, 2019 (FR) FR1904369

(51) Int. Cl. H01L 31/056; G02B 5/08

(52) U.S. Cl. CPC H01L 31/056; H01L 31/0322; G02B 5/0858

(57) ABSTRACT

The invention concerns a mirror (14), in particular for a photovoltaic cell (10), comprising a stack of layers (SC1, SC2, SC3, SC4, SC5, SC6), the layers (SC1, SC2, SC3, SC4, SC5, SC6) being superimposed along a stacking direction, the stack comprising:
a first layer (SC1) of transparent conductive oxide,
a second optical reflection layer (SC4) of metal, and
a third layer (SC6) of conductive oxide.

The present invention relates to a mirror for a photovoltaic cell. The present invention also relates to a photovoltaic cell and a photovoltaic module comprising such a mirror.

Photovoltaic solar energy is electrical energy produced from solar radiation by means of photovoltaic panels. Such energy is renewable because light energy is considered inexhaustible on a human time scale.

The photovoltaic cell is the basic electronic component of the system. It uses the photoelectric effect to convert electromagnetic waves (radiation) emitted by the sun into electricity. Several cells connected to each other form a photovoltaic solar module and these modules together form a solar system.

Many types of photovoltaic cells have been developed to increase the efficiency of a photovoltaic cell. One avenue that is being studied in particular is the realisation of photovoltaic cells based on CIGS, the abbreviation CIGS referring to the chemical formula Cu(In,Ga)(S,Se)₂.

A CIGS photovoltaic cell is commonly manufactured by depositing a layer of molybdenum on soda-lime glass. During this deposition, a layer of MoSe₂ is formed at the interface between the molybdenum layer and the CIGS layer.

The molybdenum layer has good resistance to the deposition temperatures of CIGS, typically between 500° C. and 600° C. After deposition, the layer thus forms an ohmic contact with the CIGS for the collection of charges, which in this case are holes.

However, the presence of such a layer leads to optical losses. This is because the optical reflection at the interface between CIGS and molybdenum is low, and light that is not absorbed after a first pass through the CIGS and that arrives at this interface is mainly absorbed in the molybdenum layer. This absorbed light is lost, resulting in a reduced yield for the photovoltaic cell.

Due to the formation of the additional MoSe₂ layer, non-radiative recombinations are observed at the interface between such a mirror and the CIGS layer. This results in a decrease in the performance of the solar cells.

Such a decrease is mitigated by the formation of a CIGS layer with a graded composition of Ga, which has the effect of increasing the conduction band of the semiconductor, thus pushing electrons away from the interface between the mirror and the CIGS layer to limit non-radiative recombination.

In the case of CIGS thin-film solar cells, i.e. cells with a thickness of less than 500 nm, such disadvantages are even more troublesome, as optical trapping is implemented by introducing a nanostructured mirror surface in order to reduce the thickness of the CIGS layer.

There is therefore a need for a photovoltaic cell with improved efficiency.

For this purpose, the description describes a mirror, in particular for a photovoltaic cell, comprising a stack of layers, the layers being superimposed along a stacking direction, the stack comprising a first layer of transparent conductive oxide, a second optical reflection layer of metal, and a third layer of conductive oxide.

According to particular embodiments, the mirror has one or more of the following features taken in isolation or in any combination that is technically possible:
the mirror further comprises at least one interfacing layer positioned at the interface between the second layer and either the first layer or the third layer, the interfacing layer preferably being made of titanium or chromium.
the mirror has an additional layer positioned between the first layer and the second layer, the additional layer being either ZnO:Al or formed by two layers made of a separate transparent conductive oxide.
the first layer has a sub-micron structure.
the first layer is made of a material selected from the group consisting of ITO, SnO₂F and In₂O₃:H.
the second layer is made of silver, the second layer preferably having a thickness of 50 nanometres or more.
the third layer is made of ZnO:Al.

The description also describes a photovoltaic cell with a mirror as described above.

In one embodiment, the photovoltaic cell further comprises an absorber, the absorber being selected from the list consisting of an I-III-VI₂ alloy, a chalcogenide and a kesterite.

The description also describes a photovoltaic module comprising at least one photovoltaic cell as described above.

Characteristics and advantages of the invention will become apparent upon reading the following description, given only as a nonlimiting example, referring to the attached drawings, in which:

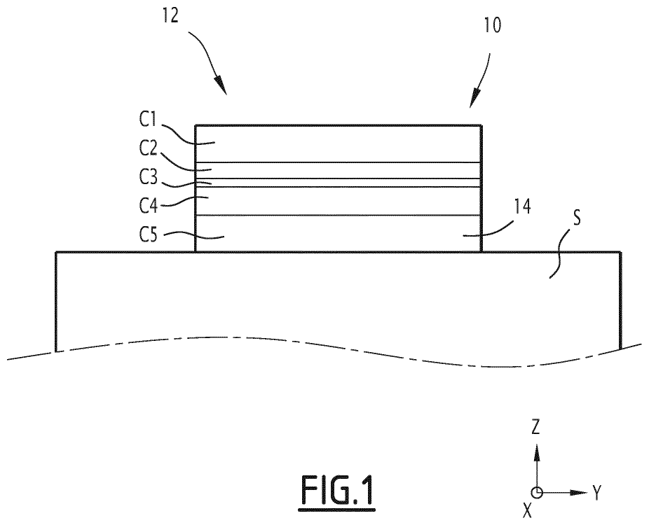

FIG. 1 is a schematic representation of an example of a photovoltaic cell comprising a stack of layers including a mirror, and

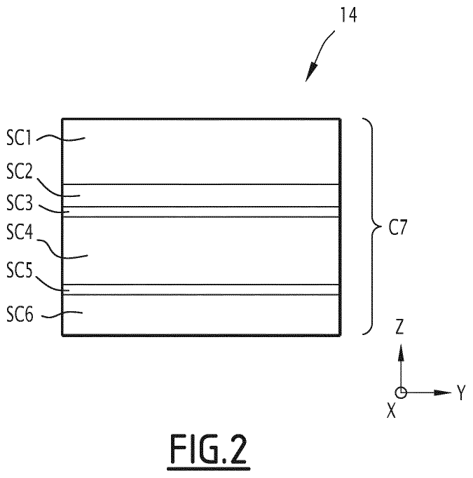

FIG. 2 is a schematic representation of an example mirror that may be used in the photovoltaic cell of FIG. 1.

A photovoltaic cell 10 is schematically represented in FIG. 1.

A photovoltaic cell is an element that converts incident solar energy into electrical energy.

The cell 10 is, for example, a CIGS thin-film cell.

A film is considered thin for a cell 10 when the thickness of the film is less than or equal to 3 micrometres (μm).

More generally, the cell 10 is made of an I-III-VI₂ alloy.

For example, element I of the periodic table is copper, element III of the periodic table is indium, gallium and/or aluminium and element VI is selenium and/or sulphur.

A set of interconnected cells 10 forms a photovoltaic module.

The cell 10 has a set 12 of layers.

The layers in the set 12 are planar layers.

The layers are superimposed along a stacking direction. The stacking direction is represented by a Z-axis in FIG. 1 and is referred to as the Z-stacking direction in the remainder of the description.

According to the example shown in FIG. 1, the set of layers comprises five layers stacked on a substrate S.

In this case, the substrate S is made of glass, in particular soda-lime glass.

Alternatively, the substrate S is made of steel or a polymer material.

The five layers of the assembly 12 are now described from top to bottom, with the topmost layer being the layer that first interacts with incident light.

The first layer C1 is a window layer.

The first layer C1 has a first thickness e1.

By definition, the thickness of a layer is the dimension of a layer along the stacking direction Z.

For example, the first thickness e1 is between 150 nanometres (nm) and 400 nm.

A quantity X is between two values A and B when the quantity X is greater than or equal to A and less than or equal to B.

In the illustrated case, the first thickness e1 is equal to 250 nm.

The first layer C1 is made of a first material M1.

In one particular example, the first material M1 is a transparent conductive oxide. The acronym TCO is often used for such a material, standing for ‘transparent conductive oxide’.

Alternatively, the first material M1 is Al:ZnO.

In another embodiment, the stack has an anti-reflective layer positioned above the first layer C1.

The second layer C2 is a second window layer.

The second layer C2 has a second thickness e2.

For example, the second thickness e2 is between 10 nm and 100 nm.

In the illustrated case, the second thickness e2 is equal to 50 nm.

The second layer C2 is made of a second material M2.

In one particular example, the second material M2 is intrinsic ZnO.

The third layer C3 serves as a buffer layer.

The third layer C3 has a third thickness e3.

For example, the third thickness e3 is between 10 nm and 50 nm.

In the illustrated case, the third thickness e3 is equal to 30 nm.

The third layer C3 is made of a third material M3.

In one particular example, the third material M3 is CdS.

Alternatively, the third material M3 is Zn(S,O,OH).

The fourth layer C4 is an active layer.

The fourth layer C4 is often called the absorber.

The fourth layer C4 has a fourth thickness e4.

The fourth thickness e4 is less than or equal to 3 μm.

For example, the fourth thickness e4 is between 100 nm and 1000 nm.

In the illustrated case, the fourth thickness e4 is equal to 500 nm.

The fourth layer C4 is made of a fourth material M4 which is CIGS in the proposed example.

The fifth layer C5 is a mirror which will be referenced as 14.

In this case, the fifth layer C5 is a plane mirror.

The fifth layer C5 has a fifth thickness e5.

For example, the fifth thickness e5 is between 50 nm and 1 μm.

The fifth layer C5 is a stack of sub-layers which is more shown in greater detail in FIG. 2.

In the proposed example, the fifth sub-layer C5 comprises six sub-layers forming a stack of layers superimposed along the stacking direction Z.

The six sub-layers forming the fifth layer C5 are now described from top to bottom, the uppermost layer being the layer that first interacts with incident light and is in contact with the sixth layer C6.

The first sub-layer SC1 provides the ohmic contact with the fourth layer C4.

The first sub-layer SC1 thus acts as a protective sub-layer that conducts charges.

The first sub-layer SC1 thus provides an electrical function, the function of collecting charges and conducting current.

The first sub-layer SC1 also serves as a diffusion barrier and ensures the stability of the mirror 14.

In particular, the first sub-layer SC1 has properties that prevent the coalescence, oxidation and sulfidation of the silver.

In particular, the first sub-layer SC1 is made of a transparent material.

The first sub-layer SC1 is made of indium-tin oxide.

Indium-tin oxide is a mixture of indium(III) oxide (In₂O₃) and tin(IV) oxide (SnO₂). Such a material is also called tin-doped indium oxide or ITO. The abbreviation ITO stands for “indium tin oxide”.

More generally, the first sub-layer SC1 is made of a material which is a transparent conductive oxide or TCO material as mentioned above.

For example, according to other variants, the first sub-layer SC1 is made of SnO₂:F or In₂O.

The second sub-layer SC2 is used to conduct the current.

The second sub-layer SC2 also serves as a diffusion barrier and ensures the stability of the mirror 14.

In particular, the second sub-layer SC2 is made of a transparent material.

Preferably, the second sub-layer SC2 is made of a different material than the first sub-layer SC1, or has a different morphology (grain size). Thus, residual diffusion of species at the grain boundaries of the second sub-layer SC2 will be unlikely to diffuse to the grain boundaries of the first sub-layer SC1.

The second sub-layer SC2 is made of ZnO:Al.

More generally, any TCO material can be used to make the second sub-layer SC2.

The second sub-layer SC2 has a thickness between 20 nm and 300 nm.

The third sub-layer SC3 serves as an interfacing or bonding layer.

The third sub-layer SC3 improves the adhesion between the second sub-layer SC2 and the fourth sub-layer SC4.

The third sub-layer SC3 is made of Ti.

The third sub-layer SC3 is thus made of a metallic material.

In particular, chromium Cr can be used to form the third sub-layer SC3.

The third sub-layer SC3 has a thickness between 0.5 nm and 5 nm.

In particular, the third sub-layer SC3 has a thickness of less than 1 nanometre to limit the absorption of incident light.

The fourth sub-layer SC4 is a reflective sub-layer, in particular for incident light with a wavelength between 400 nm and 1.2 μm, which corresponds to the visible and near-infrared ranges.

According to the proposed example, the fourth sub-layer SC4 provides two distinct functions: an electrical function and an optical function.

The electrical function is, in the case described, to provide lateral conductivity for current collection at the edge of the photovoltaic cell 10.

The optical function is to reflect the incident light onto the fourth sub-layer SC4.

The fourth sub-layer SC4 is made of Ag.

More generally, the material forming the fourth sub-layer SC4 is a metallic material.

In particular, Au, Cu or Al can be used to form the fourth sub-layer SC4.

The fourth sub-layer SC4 has a thickness between 50 nm and 200 nm.

Preferably, the fourth sub-layer SC4 has a thickness between 100 nm and 150 nm.

In the proposed example, the same comments as for the third sub-layer SC3 are valid for the fifth sub-layer SC5 and are not repeated here. The only difference is that the fifth sub-layer SC5 improves the adhesion between the fourth sub-layer SC4 and the sixth sub-layer SC6 and not between the second sub-layer SC2 and the fourth sub-layer SC4.

Furthermore, for the case of FIG. 2, the third sub-layer SC3 and the fifth sub-layer SC5 are identical.

However, the thickness of the fifth sub-layer SC5 can be much greater than 1 nm, as the fifth sub-layer SC5 has no optical function.

The sixth sub-layer SC6 is made of ZnO:Al.

Such a material is more often referred to as AZO, which stands for “aluminum-doped zinc oxide”.

More generally, the sixth sub-layer SC6 is made of a TCO material.

In particular, in one embodiment, the sixth sub-layer SC6 is made of ITO.

In yet another embodiment, the material forming the sixth sub-layer SC6 is a conductive material that does not have the property of being transparent.

In particular, a material such as Ti can be considered.

The sixth sub-layer SC6 has a thickness between 20 nm and 300 nm.

Preferably, the sum of the seven thicknesses is less than 500 nanometres.

The operation of the layer stack is described in the following.

The incident light on the cell 10 passes through the first layer C1 and the second layer C2, which ensures that the portion transmitted to the other layers is maximised.

The active layer C4 then absorbs the incident light.

The light escaping towards the mirror 14 is reflected and then absorbed again by the active layer C4.

Tests carried out by the applicant have shown that the performance achieved with the mirror 14 corresponds to an improved efficiency compared to a molybdenum mirror 14.

This is because the mirror 14 has a better reflection than the reflection provided by a molybdenum layer.

The proposed mirror 14 is also stable at temperatures of 500° C. and above.

In addition, the mirror 14 is also adapted to form an ohmic contact with the absorber.

In addition, the mirror 14 is easily manufactured at the same time as the other layers forming the cell 10.

During the manufacturing process, the different layers are laid on top of each other.

In particular, the mirror 14 can be obtained with easy-to-implement deposition techniques, including sputtering or electron evaporation techniques.

During the deposition of the fourth layer C4, the temperature is preferably less than or equal to 500° C.

This avoids the formation of Ga₂O₃ oxide at the interface between the first ITO sub-layer SC1 and the fourth layer C4. The presence of such a Ga₂O₃ layer deteriorates the performance of the cell 10.

An alternative way to circumvent such a problem is to insert a layer of Al₂O₃ between the first ITO sub-layer SC1 and the fourth layer C4, the Al₂O₃ layer being a thin layer, typically 3 nm.

The manufacture of the proposed cell 10 is therefore compatible with mass production.

The mirror 14 allows the thickness of the fourth layer C4 to be reduced by a factor of 2 without changing the absorption of the fourth layer C4. As a result, the current density of the cell 10 increases.

It should also be noted that the mirror 14 is compatible with other absorber materials.

In particular, the mirror 14 can be used with a chalcogenide material for the absorber.

A chalcogenide is the name of the negative ion formed from a chemical element of the chalcogen family that has gained two electrons. The chalcogens correspond to the elements in the sixteenth column of the periodic table, which includes sulphur and selenium.

For example, the chalcogenide material is Cu(In,Ga)Se₂, CuInSe₂, CuGaSe₂ and CuInTe2₂.

In another case, the mirror 14 is used with a kesterite material for the absorber.

A kesterite material is a quaternary semiconductor of the form I₂-II-IV-VI₄ and tetragonal crystal structure such as copper-zinc-tin-selenide (CZTSe) and CZTSSe-sulphide-selenide alloys.

As an example, the kesterite material is CZTS (Cu₂ZnSnS₄).

A particular example is Cu₂ZnSnS₄ (also called CZTS).

The mirror 14 is also compatible with several types of substrates such as glass, flexible steel (e.g. stainless steel) or a polymer, e.g. polyimide.

Other stacking options are possible to achieve the same benefits.

For example, it is interesting to consider a stack without the third sub-layer C3 and without the fifth sub-layer C5.

In such a case, a stack of ITO/ZnO:Al/Ag/ZnO:Al could be considered.

By way of illustration, the first sub-layer SC1 has a thickness of 30 nm, the second sub-layer SC2 has a thickness of 30 nm, the fourth sub-layer SC4 has a thickness of 100 nm and the sixth sub-layer SC6 has a thickness of 30 nm.

The total thickness is then less than 300 nm, which is the minimum size obtained with a molybdenum mirror.

According to another particular example, the second sub-layer SC2 is not present.

In yet another example, the material of the sixth sub-layer SC6 is another oxide.

In this case, the sixth SC6 sub-layer plays the same role of thermal stability and diffusion barrier.

In a particular embodiment, the second sub-layer SC2 is formed by two layers made of a different TCO material.

Such a design improves the stability of the mirror 14 at high temperatures.

Other variants can be considered to improve optical trapping.

In particular, according to one embodiment, the mirror 14 is structured on a sub-micron scale.

Such sub-micron structuring is, for example, achieved by structuring only the first sub-layer SC1.

In such a case, the method of manufacturing the mirror 14 involves depositing each sub-layer on a planar substrate and then etching the first sub-layer SC1 by a lithography technique followed by plasma or chemical etching.

Such a structured mirror 14 increases the optical path in the absorber. The increase can be up to a factor of 2 in the case of a perfectly reflecting plane mirror, and more than a factor of 2 in the case of a structured mirror.

Such a mirror 14 is thus adapted to form part of an optoelectronic device comprising an absorber. In particular, such a mirror 14 is also suitable for active optoelectronic devices such as light emitters.

For such an adaptation, it is sufficient that the mirror 14 comprises the substrate S as well as three sub-layers, namely the first sub-layer SC1 of transparent conductive oxide, the fourth sub-layer SC4 of metal optical reflection, and the sixth sub-layer SC6 of conductive oxide.

By defining an order relative to the substrate S, a layer closer to the substrate S being a lower layer and a layer further from the substrate S being a higher layer. From top to bottom, the mirror 14 comprises the first sub-layer SC1, the fourth sub-layer SC4 and the sixth sub-layer SC6. This means, in particular, that the sixth sub-layer SC6 is between the fourth sub-layer SC4 and the substrate S.

The mirror 14 forms an ohmic contact with the absorber. Such a contact is a metal/semiconductor contact that allows current to flow (charge collection) without resistive losses. In other words, the ohmic contact ensures that the current I and the voltage V are proportional.

1. Mirror, comprising a stack of layers, the layers being superimposed along a stacking direction, the stack comprising:
a first layer of transparent conductive oxide,
a second optical reflection layer of metal, and
a third layer of conductive oxide.

2. Mirror according to claim 1, wherein the mirror further comprises at least one interfacing layer positioned at the interface between the second layer and either the first layer or the third layer, the interfacing layer preferably being made of titanium or chromium.

3. Mirror according to claim 1, wherein the mirror has an additional layer positioned between the first layer and the second layer, the additional layer being either of ZnO:Al or formed by two layers made of a separate transparent conductive oxide.

4. Mirror according to claim 1, wherein the first layer has a sub-micron structuring.

5. Mirror according to claim 1, wherein the first layer is made of a material selected from the group consisting of ITO, SnO₂F and In₂O₃:H.

6. Mirror according to claim 1, wherein the second layer is made of silver, the second layer preferably having a thickness greater than or equal to 50 nanometers.

7. Mirror according to claim 1, wherein the third layer is made of ZnO:Al.

8. Photovoltaic cell comprising a mirror according to claim 1.

9. Photovoltaic cell according to claim 8, the photovoltaic cell further comprising an absorber, the absorber being selected from the list consisting of an I-III-VI₂ alloy, a chalcogenide and a kesterite.

10. Photovoltaic module comprising at least one photovoltaic cell according to claim 8.
